(19) United States
(12) Patent Application Publication
(10) Pub. No.: US 2012/0314377 A1
(43) Pub. Date: Dec. 13, 2012

(54) PACKAGING STRUCTURE EMBEDDED WITH ELECTRONIC ELEMENTS AND METHOD OF FABRICATING THE SAME

(75) Inventors: Chien-Kuang Lai, Taoyuan (TW); Chih-Kuei Yang, Taoyuan (TW); Ming-Chieh Chiu, Taoyuan (TW)

(73) Assignee: UNIMICRON TECHNOLOGY CORPORATION, Taoyuan (TW)

(21) Appl. No.: 13/483,238

(22) Filed: May 30, 2012

(30) Foreign Application Priority Data
Jun. 7, 2011 (TW) 100119892

(51) Int. Cl. H05K 7/06; B32B 37/12

(52) U.S. Cl. 361/729; 156/292

(57) ABSTRACT

A packaging structure is provided which includes: a substrate, at least an electronic module, and an adhesive material. The substrate has two opposing surfaces, at least an opening penetrating the two surfaces, and two metallic frames formed on two opening ends of the at least an opening. The electronic module is disposed in the opening and has electronic elements and an encapsulant encapsulating the electronic elements. Each of the electronic elements has two opposing active surfaces exposed from the encapsulant and electrode pads formed on the two opposing active surfaces. The electrode pads are exposed from the opening. The adhesive material is filled into the opening and a gap between the electronic module and the opening, so as to secure in position the electronic modules in the opening. Compared with the prior art, the embedded electronic elements of the packaging structure according to the present invention is prevented from short circuit, and thus has increased yield rate.

### BACKGROUND OF THE INVENTION

1. Field of the Invention

The present invention relates generally to packaging structures and methods of fabricating the same, and, more particularly, to a packaging structure embedded with electronic elements and a method of fabricating the same.

2. Description of Related Art

A semiconductor device may be fabricated in a wire bonding manner or a flip-chip manner. The semiconductor device may also have a packaging substrate and electronic elements (e.g., semiconductor chips) embedded therein. Such a semiconductor device has a reduced volume and enhanced electric functionalities.

FIGS. 1A and 1B are cross-sectional views illustrating a method of fabricating a packaging structure embedded with electronic elements according to the prior art, wherein FIG. 1B′ is a top view of FIG. 1B.

As shown in FIG. 1A, a substrate 10 and a plurality of electronic elements 13 are provided. The substrate 10 has two opposing surfaces 101, an opening 100 penetrating the two surfaces 101, two metallic frames 11 formed on the two surfaces 101 surrounding two opening ends of the opening 100, and at least one conductive via 12 penetrating the two surfaces 101. Each of the electronic elements 13 has two opposing active surfaces 131 and electrode pads 132 formed on the active surfaces 131.

As shown in FIGS. 1B and 1B′, an adhesive material 14 is employed to secure the electronic elements 13 in the opening 100. The electrode pads 132 are exposed from the opening 100. The adhesive material 14 is filled into a gap between the electronic elements 13 and the opening 100.

However, the electronic elements 13 are likely in contact with one another (as shown in FIGS. 1B and 1B′) or with circuits on the substrate 10. As a result, the packaging structure tends to incur a short circuit problem. Although the location of the electronic elements 13 may be controlled by adjusting the process parameters, the improvement is limited, and still can not effectively improve the overall yield.

Therefore, it is desirable to provide a packaging structure embedded with electronic elements and a method of fabricating the same in order to overcome the above drawbacks of the prior art.

### SUMMARY OF THE INVENTION

In view of the above drawbacks of the prior art, the present invention provides a packaging structure embedded with electronic elements and a method of fabricating the same.

To achieve the above-mentioned and other objectives, the present invention provides a packaging structure embedded with electronic elements, including: a substrate having two opposing surfaces and at least an opening penetrating the two surfaces; two metallic frames respectively formed at two opening ends of the at least an opening on the two surfaces; at least an electronic module disposed in the opening and having electronic elements and an encapsulant encapsulating the electronic elements, wherein each of the electronic elements has two opposing active surfaces exposed from the encapsulant and electrode pads formed on the two opposing active surfaces and exposed from the opening; and an adhesive material filled into a gap between the electronic module and the opening, to secure in position the electronic module in the opening.

The present invention further provides a method of fabricating a packaging structure, comprising: providing a substrate and at least an electronic module having a plurality of electronic elements, wherein each of the electronic elements has two opposing active surfaces and electrode pads formed on the two opposing active surfaces, the substrate has two opposing surfaces, at least an opening penetrating the two surfaces and two metallic frames formed on a periphery of the opening, and the electronic module has an encapsulant encapsulating the electronic elements, the encapsulant has an encapsulant opening for the two opposing active surfaces of each of the electronic elements to be exposed therefrom; and filling an adhesive material into a gap between the electronic module and the opening, to secure in position the electronic module in the opening, with the electrode pads being exposed from the opening.

Compared with the prior art, the present invention encapsulates the periphery of the plurality of electronic elements with the encapsulant and combines the electronic elements into an electronic module electrically insulating with each other, and the electronic module is disposed in the opening of the substrate. The periphery of each of the electronic elements is encapsulated with the insulated encapsulant, such that the electronic elements will not short circuit to each other and will not contact the circuits on the substrate, thus allowing the packaging structure embedded with the electronic elements to be prevented from the short circuit caused by undesired electrical connection, in order to effectively improve the overall yield and reliability.

### BRIEF DESCRIPTION OF DRAWINGS

FIGS. 1A to 1B are cross-sectional views illustrating a method of fabricating a packaging structure embedded with electronic elements according to the prior art, wherein FIG. 1B′ is a top view of FIG. 1B; and

FIGS. 2A to 2C are cross-sectional views illustrating a method of fabricating a packaging structure embedded with electronic elements according to the present invention, wherein FIG. 2B′ is a top view of FIG. 2B.

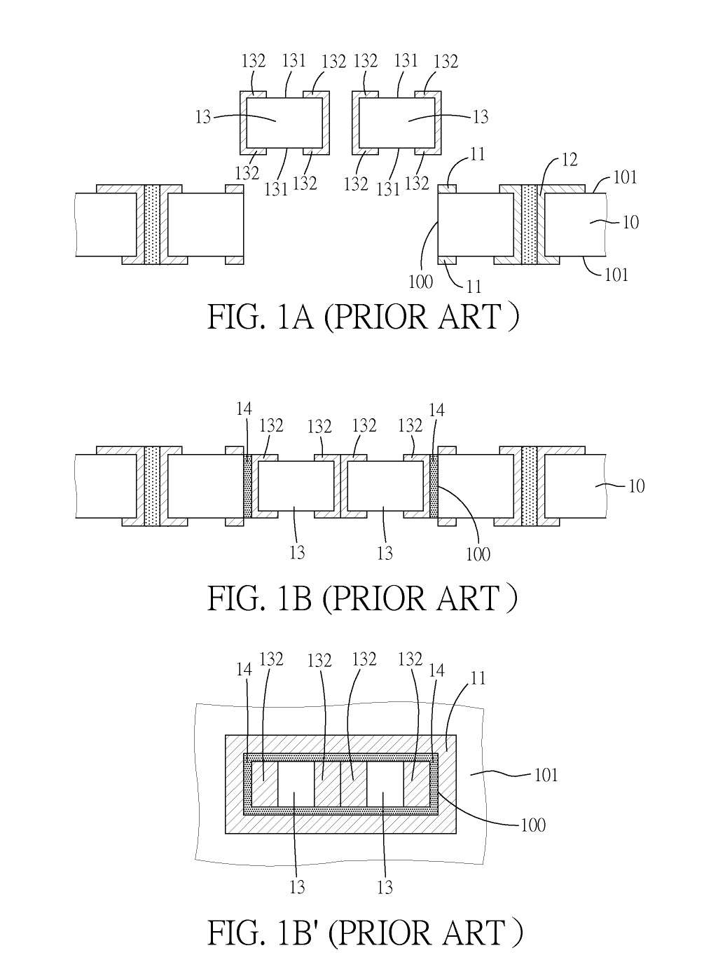

### DETAILED DESCRIPTION OF PREFERRED EMBODIMENTS

It is to be understood that both the foregoing general descriptions and the detailed embodiments are exemplary and are, together with the accompanying drawings, intended to provide further explanation of technical features and advantages of the invention.

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be devised without departing from the spirit of the present invention.

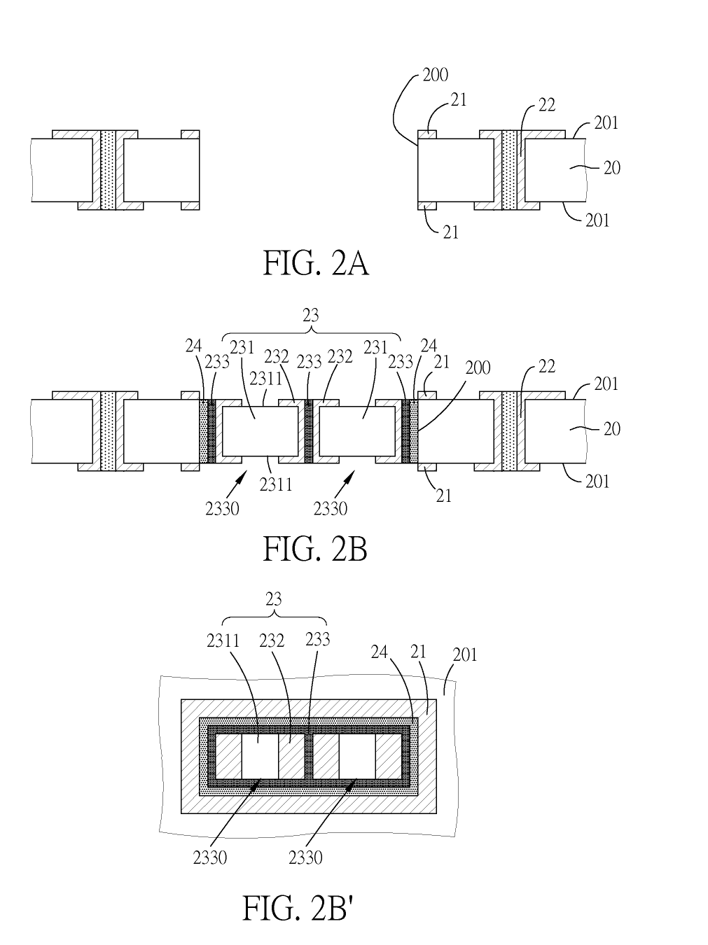

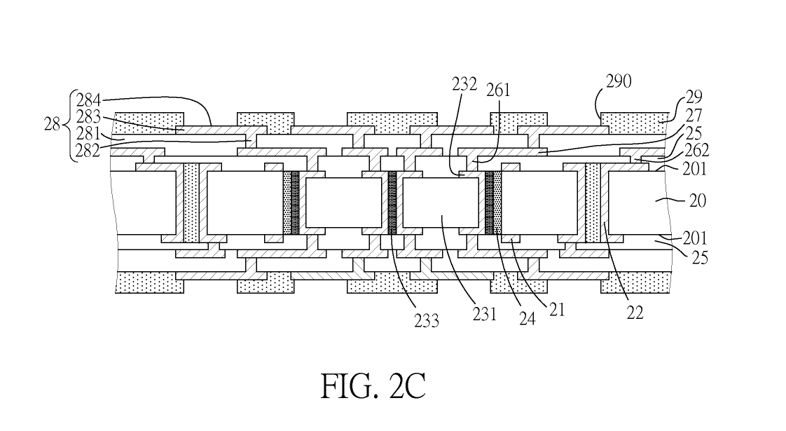

FIGS. 2A to 2C are cross-sectional views illustrating a method of fabricating a packaging structure embedded with electronic elements according to the present invention, wherein FIG. 2B′ is a top view of FIG. 2B.

As shown in FIG. 2A, a substrate 20 is provided. The substrate 20 has two opposing surfaces 201, an opening 200 penetrating the two surfaces 201, two metallic frames 21 respectively formed on the two surfaces 201 surrounding two opening ends of the opening 200, and at least one conductive via 22 penetrating the two surfaces 201.

As shown in FIGS. 2B and 2B′, an electronic module 23 having a plurality of electronic elements 231 is provided. Each of the electronic elements 231 has two opposing active surfaces 2311 and electrode pads 232 formed on the active surfaces 2311. The electronic module 23 includes an encapsulant 233 encapsulating the electronic elements 231. The encapsulant 233 has an encapsulant opening 2330 for the two opposing active surfaces 2311 of the electronic elements 231 to be exposed therefrom. An adhesive material 24 is used to secure in position the electronic module 23 in the opening 200 and the electrode pads 232 are exposed from the opening 200. The adhesive material 24 is filled into a gap between the electronic module 23 and the opening 200. At least one of the electronic elements 231 is a multi-layered ceramic capacitor (MLCC).

As shown in FIG. 2C, a first dielectric layer 25 is formed on at least one surface 201 of the substrate 20 and the active surfaces 2311 of the electronic elements 231 at the same side, and a first wiring layer 27 is formed on the first dielectric layer 25. A plurality of first conductive blind vias 261 for electrically connecting the first wiring layer 27 with the electrode pads 232 and a plurality of third conductive blind vias 261 for electrically connecting the first wiring layer 27 with the conductive vias 22 are formed in the first dielectric layer 25. A built-up structure 28 is formed on the first dielectric layer 25 and the first wiring layer 27. The built-up structure 28 includes at least one second dielectric layer 281, a second wiring layer 283 formed on the second dielectric layer 281, and a plurality of second conductive blind via 282 formed in the second dielectric layer 281 and electrically connected to the first wiring layer 27 and the second wiring layer 283. The second wiring layer 283 of the outermost of the built-up structure 28 includes a plurality of conductive pads 284. An insulating protective layer 29 is formed on the outermost layer of the built-up structure 28, and the insulating protective layer 29 has a plurality of insulating protective layer openings 290 for the conductive pads 284 to be exposed therefrom correspondingly.

In an embodiment, a packaging structure includes a substrate 20 having two opposing surfaces 201, an opening 200 penetrating the two surfaces 201, and two metallic frames 21 formed on the surfaces 201 surrounding the two opening ends of the opening 200; an electronic module 23 disposed in the opening 200 and having a plurality of electronic elements 231 and an encapsulant 233 encapsulating the electronic elements 231, wherein each of the electronic elements 231 has two opposing active surfaces 2311 exposed from the encapsulant 233 and electrode pads 232 formed on the two opposing active surfaces 2311, and the electrode pads 232 are exposed from the opening 200; and an adhesive material 24 filled into the gap between the electronic module 23 and the opening 200, so as to secure in position the electronic module 23 in the opening 200.

The packaging structure further includes a first dielectric layer 25 and a first wiring layer 27. The first dielectric layer 25 is formed on at least one surface 201 of the substrate 20 and the active surfaces 2311 of the electronic elements 231 at the same side. The first wiring layer 27 is formed on the first dielectric layer 25. A plurality of first conductive blind vias 261 for electrically connecting the first wiring layer 27 with the electrode pads 232 are formed in the first dielectric layer 25. A built-up structure 28 is formed on the first dielectric layer 25 and the first wiring layer 27. The built-up structure 28 includes at least one second dielectric layer 281, second wiring layer 283 formed on the second dielectric layer 281, and a plurality of second conductive blind vias 282 formed in the second dielectric layer 281 and electrically connecting the first wiring layer 27 and the second wiring layer 283. The second wiring layer 283 of the outermost layer of the built-up structure 28 includes a plurality of conductive pads 284.

In the packaging structure according to the present invention, an insulating protective layer 29 is formed on the outermost layer of the built-up structure 28, and the insulating protective layer 29 has a plurality of insulating protective layer openings 290 for the conductive pads 284 to be exposed therefrom correspondingly.

According to the packaging structure embedded with electronic elements, a plurality of third conductive blind vias 262 for electrically connecting the first wiring layer 27 with the conductive vias 22 are formed in the first dielectric layer 25. The substrate 20 has at least one conductive via 22 penetrating the two surfaces 201. The electronic element 231 may be a multi-layered ceramic capacitor.

In summary, compared to the prior art, the present invention encapsulates the periphery of each of the plurality of electronic elements by the encapsulant and incorporates the plurality of electronic elements into an electronic module electrically insulating with each other, and the electronic module is disposed in the opening of the substrate. The periphery of each of the electronic elements is encapsulated by the insulated encapsulant, such that the electronic elements will not be short-circuited to each other and will not be in contact with the circuits on the substrate, thus allowing the packaging structure embedded with electronic elements to be prevented from short circuit, in order to effectively improve the overall yield and reliability.

The above embodiments are illustrated to disclose the preferred implementation according to the present invention but not intended to limit the scope of the present invention, Accordingly, all modifications and variations completed by those with ordinary skill in the art should fall within the scope of present invention defined by the appended claims.

What is claimed is:

1. A packaging structure, comprising:
a substrate having two opposing surfaces and at least an opening penetrating the two surfaces;
two metallic frames formed at two opening ends of each of the at least an opening on the two surfaces;
a plurality of electronic modules disposed in the opening and having electronic elements and an encapsulant encapsulating the electronic elements, wherein each of the electronic elements has two opposing active surfaces exposed from the encapsulant and electrode pads formed on the two opposing active surfaces and exposed from the opening; and
an adhesive material filled into a gap between the electronic module and the opening, to secure in position the electronic module in the opening.

2. The packaging structure of claim 1, further comprising a built-up structure formed on one of the two surfaces of the substrate, wherein the built-up structure has a dielectric layer, a wiring layer formed on the dielectric layer, and a plurality of conductive pads formed on the wiring layer.

3. The packaging structure of claim 2, wherein the built-up structure further comprises an insulating protective layer formed on the wiring layer, and the insulating protective layer is formed with a plurality of insulating protective layer openings for the conductive pads to be exposed therefrom.

4. The packaging structure of claim 1, wherein the substrate further comprises a plurality of conductive vias penetrating the two surfaces.

5. The packaging structure of claim 1, wherein at least one of the electronic elements is a multi-layered ceramic capacitor.

6. A method of fabricating a packaging structure, comprising:
providing a substrate and at least an electronic module having a plurality of electronic elements, wherein each of the electronic elements has two opposing active surfaces and electrode pads disposed on the two opposing active surfaces, the substrate has two opposing surfaces, at least an opening penetrating the two surfaces and two metallic frames respectively formed on two opening ends of each of the at least an opening, and the electronic module has an encapsulant encapsulating the electronic elements and having an encapsulant opening for the two opposing active surfaces of each of the electronic elements to be exposed therefrom; and
filling an adhesive material into a gap between the electronic module and the opening to secure in position the electronic module in the opening, with the electrode pads being exposed from the opening.

7. The method of claim 6, further comprising forming on at least one of the two opposing surfaces of the substrate a built-up structure having a dielectric layer formed on one of the two surfaces of the substrate, a wiring layer formed on the dielectric layer, and a plurality of conductive pads formed on the wiring layer.

8. The method of claim 6, wherein the substrate has a plurality of conductive vias penetrating the two surfaces.

9. The method of claim 6, wherein at least one of the electronic elements is a multi-layered ceramic capacitor.
